(19) United States
(12) Patent Application Publication
(10) Pub. No.: US 2007/0152654 A1
(43) Pub. Date: Jul. 5, 2007

(54) Integrated circuit (IC) transporting device for IC probe apparatus

(76) Inventor: Herbert Tsai, Taipei City (TW)

Correspondence Address: LEONG C LEI, PMB # 1008, 1867 YGNACIO VALLEY ROAD, WALNUT CREEK, CA, 94598, US

(21) Appl. No.: 09/853,720

(22) Filed: May 14, 2001

(51) Int. Cl. G01R 31/28

(52) U.S. Cl. 324/158.1

(57) ABSTRACT

An IC transporting device for IC probe apparatus includes a vertical unit, a horizontal unit and a suck-and-hold unit, and capable of being set, change by means of a computer program and controlling to-and-fro moving distance of individual motor so as to accurately position the transporting device, wherein the vertical unit includes a main sliding rail of an appropriate distance and a step motor at the front and rear end, and the main sliding rail is mounted with a dove-tail block having a clipping block with an arch-shaped block; the horizontal unit includes an arch-shaped block having a suspension arm being mounted onto an upright board and a flat board, and the perpendicular face of the upright board has a first step motor and a second step motor, and a common sharing sliding rail is provided on the flat board for left-right movement of a first and a second suck-and-hold device driven by the first and the second step motor; the suck-and-hold unit includes a first suck-and-hold device, and the first suck-and-hold device has a L-shaped sliding seat having a dove-tail slot at the bottom thereof and the sliding seat is vertically mounted at a belt of the first step motor and the external edge of the sliding seat is mounted with a step motor, and the sliding seat is provided with a L-shaped board to engage with the teeth stripe of the step motor, the rear end of the L-shaped board is provided with a vacuum nozzle so as to suck and retain the chip; the second suck-and-hold device has a L-shaped sliding seat having a dove-tail slot at the bottom thereof, and the vertical section of the sliding seat is mounted at the belt stripe of the second step motor the belt drives the entire sliding seat so that the entire seat swing to left and right at a suspension arm, the external edge of the sliding seat is provided with a step motor and a L-shaped corner board for the engagement with the teeth stripe of the step motor, and the end terminal of the L-shaped corner board is provided with vacuum nozzle to suck the chips.

### BACKGROUND OF THE INVENTION

(a) Field of the Invention

The present invention relates to an IC transporting device for IC probe apparatus, and in particular, a transporting device having two arms suck and access IC chips simultaneously and the distance between each suction nozzle being changeable by means of a program. The transporting device has a main sliding rail mounted with a suspension arm, and the suspension arm is provided with an upright board and a flat board. A sliding rail is provided on the flat board for the sliding of the two suck-and-hold unit for sliding movement. The step-motor gear and belt mounted on the upright board drive the suck-and-hold unit. The fastener for the nozzle tube of the suck-and-hold unit is provided with at least one L-shaped corner board so as to provide a minimum distance between two nozzles.

(b) Description of the Prior Art

IC products are tested in two stages, i.e., circuit probe or wafer sort and final test (package test). Final test is only carried out when the product is packaged. This is to ensure after the packaging stage, the chip can still comply with requirement. FIG. 1 shows a conventional IC transporting structure of an IC probe apparatus. This convention device 1′ has an axial moving mechanism 11′ to provide the entire movement of the IC chip transporting apparatus 1′. The moving mechanism 11′ is provided with suck-and-hold unit 2′ having a fixed gap. Nozzles 21′ are used to suck IC chips 31′ on the IC holding tray 3′. The drawbacks of this conventional device are that the gap of the suck-and-hold unit 2′ is fixed and thus, the gap of the nozzle has only one type. If another different size chip is to be tested, another different size suck-and-hold unit has to be changed. This is rather inconvenient. As the present trend of the semiconductor industries employ system on a chip, RF (Radio Frequency Specification), and as a result of frequent change of the suck-and-hold unit, the productivity of the entire apparatus cannot be increased.

### SUMMARY OF THE INVENTION

Accordingly, it is an object of the present invention to provide an IC transporting device for IC probe apparatus, which mitigates the drawbacks of the conventional transporting structure for IC in an IC probe apparatus.

Yet another object of the present invention is to provide an IC transporting device for IC probe apparatus, wherein by means of a vertical unit, a horizontal unit, and a perpendicular unit of a suck-and-hold unit to provide three axes movement function, and at least one sliding seat of the suck-and-hold unit is provided with a L-shaped board for the mounting of nozzles, such that the smallest distance between two nozzles is obtained, thereby the device provides capability of wide scope chip testing.

Yet another object of the present invention is to provide an IC transporting device for IC probe apparatus, wherein the position of the three axes can be done by programs and by means of the programs, the positioning of the axial path can be changed, and the distance between the two nozzles of the suck-and-hold unit can be appropriately adjusted without manual adjustment or calibration, thus, the production efficiency is increased.

The foregoing objects and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a conventional IC transporting structure of an IC probe apparatus.

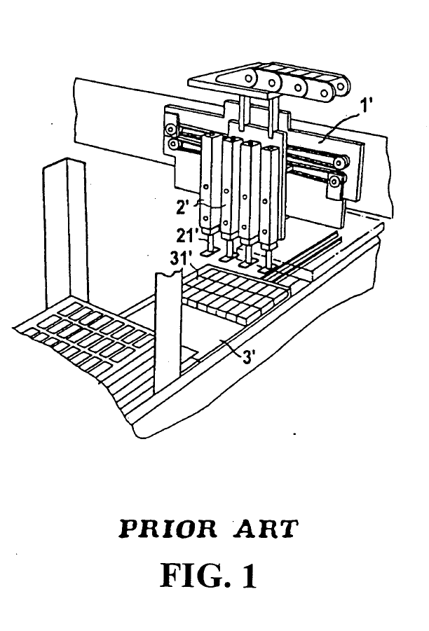

FIG. 2 is a perspective view of the present invention.

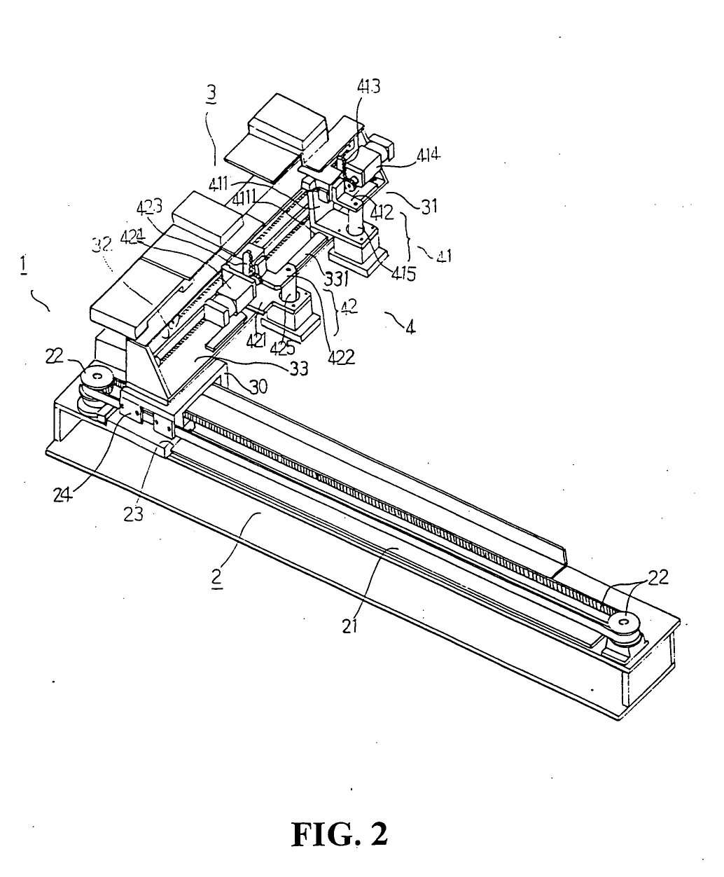

FIG. 3 is a schematic view showing the movement of the vertical axis (Y-axis) in accordance with the present invention.

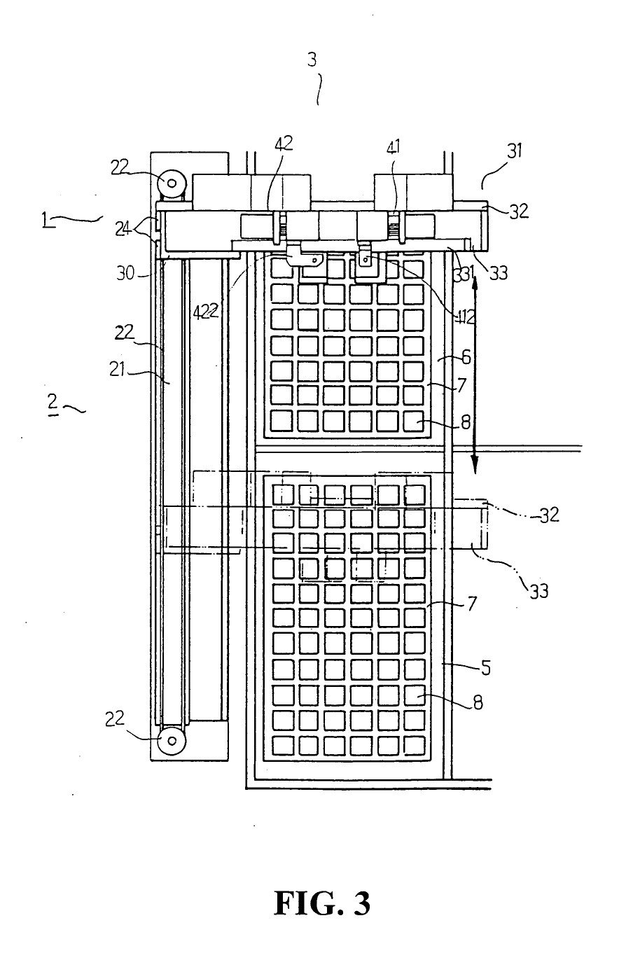

FIG. 4 is a schematic view showing the gap adjustment of the suck-and-hold head horizontal axis (x-axis) and the movement of vertical axis of the suck-and hold IC chip in accordance with the present invention.

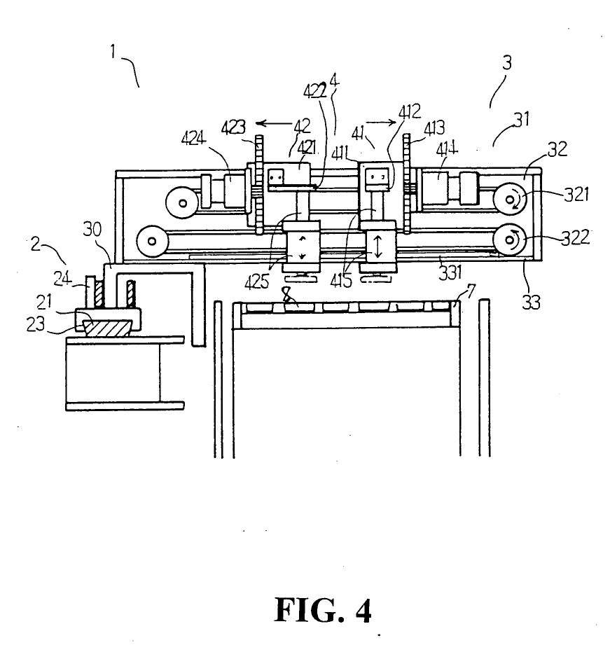

### DETAILED DESCRIPTION OF THE PRESENT INVENTION

For the purpose of promoting an understanding of the principles of the invention, reference will now be made to the embodiment illustrated in the drawings. Specific language will be used to describe same. It will, nevertheless, be understood that no limitation of the scope of the invention is thereby intended, alterations and further modifications in the illustrated device, and further applications of the principles of the invention as illustrated herein being contemplated as would normally occur to one skilled in the art to which the invention relates.

An IC transporting device for IC probe apparatus comprising a vertical unit, a horizontal unit and a suck-and-hold unit, and capable of being set, change by means of a computer program and controlling to-and-fro moving distance of individual motor so as to accurately position the transporting device, wherein the vertical unit includes a main sliding rail of an appropriate distance and a step motor at the front and rear end, and the main sliding rail is mounted with a dove-tail block having a clipping block with an arch-shaped block; the horizontal unit includes an arch-shaped block having a suspension arm being mounted onto an upright board and a flat board, and the perpendicular face of the upright board has a first step motor and a second step motor, and a common sharing sliding rail is provided on the flat board for left-right movement of a first and a second suck-and-hold device driven by the first and the second step motor; the suck-and-hold unit includes a first suck-and-hold device, and the first suck-and-hold device has a L-shaped sliding seat having a dove-tail slot at the bottom thereof and the sliding seat is vertically mounted at a belt of the first step motor and the external edge of the sliding seat is mounted with a step motor, and the sliding seat is provided with a L-shaped board to engage with the teeth stripe of the step motor, the rear end of the L-shaped board is provided with a vacuum nozzle so as to suck and retain the chip; the second suck-and-hold device has a L-shaped sliding seat having a dove-tail slot at the bottom thereof, and the vertical section of the sliding seat is mounted at the belt stripe of the second step motor the belt drives the entire sliding seat so that the entire seat swing to left and right at a suspension arm, the external edge of the sliding seat is provided with a step motor and a L-shaped corner board for the engagement with the teeth stripe of the step motor, and the end terminal of the L-shaped corner board is provided with vacuum nozzle to suck the chips.

In accordance with the present invention, a program is used to control vertical step motor so as to provide appropriate to-and-fro movement in appropriate time between the region A and region B of the chip holding disc. The first step motor and the second step motor at the horizontal axis can be controlled by the computer program After the distance between the first suck-and-hold device and the second suck-and-hold device are appropriately adjusted with respect to position, by means of the driving of the gear strap and the step motor within the two suck-and-hold device, the chip at region A is sucked by vacuum via nozzle and is placed by the vertical unit to an appropriate position at the region B.

In accordance with the present invention, the sliding seat of the suck-and-hold unit is provided with an L-shaped board so as to obtain the smallest gap between two nozzles to suck-and-hold of smallest chip gap scope to provide wider application.

In view of the above, the present invention employs programmable suck-and-hold unit so as to modify the gap distance between two suck and hold unit without changing the suck-and-hold unit in case of change of chip size. In addition, the entire suck-and-hold unit employs a pair of vacuum suction nozzle to simultaneously suck and hold the chips to simultaneously position the chips. This device effectively increases the capability of chip transportation.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. An IC transporting device for IC probe apparatus comprising a vertical unit, a horizontal unit and a suck-and-hold unit, and capable of being set, change by means of a computer program and controlling to-and-fro moving distance of individual motor so as to accurately position the transporting device, wherein
(a) the vertical unit includes a main sliding rail of an appropriate distance and a step motor at the front and rear end, and the main sliding rail is mounted with a dove-tail block having a clipping block with an arch-shaped block;
(b) the horizontal unit includes an arch-shaped block having a suspension arm being mounted onto an upright board and a flat board, and the perpendicular face of the upright board has a first step motor and a second step motor, and a common sharing sliding rail is provided on the flat board for left-right movement of a first and a second suck-and-hold device driven by the first and the second step motor;
(c) the suck-and-hold unit includes a first suck-and-hold device, and the first suck-and-hold device has a L-shaped sliding seat having a dove-tail slot at the bottom thereof and the sliding seat is vertically mounted at a belt of the first step motor and the external edge of the sliding seat is mounted with a step motor, and the sliding seat is provided with a L-shaped board to engage with the teeth stripe of the step motor, the rear end of the L-shaped board is provided with a vacuum nozzle so as to suck and retain the chip; the second suck-and-hold device has a L-shaped sliding seat having a dove-tail slot at the bottom thereof, and the vertical section of the sliding seat is mounted at the belt stripe of the second step motor the belt drives the entire sliding seat so that the entire seat swing to left and right at a suspension arm, the external edge of the sliding seat is provided with a step motor and a L-shaped corner board for the engagement with the teeth stripe of the step motor, and the end terminal of the L-shaped corner board is provided with vacuum nozzle to suck the chips.
